(19) United States
(12) Patent Application Publication
(10) Pub. No.: US 2012/0133444 A1
(43) Pub. Date: May 31, 2012

(54) PHASE-LOCKED LOOP DEVICE AND CLOCK CALIBRATION METHOD THEREOF

(75) Inventors: CHAO-WEN TZENG, Taichung City (TW); PEI-YING CHAO, Taipei City (TW); SHAN-CHIEN FANG, Taipei City (TW); SHI-YU HUANG, Taoyuan County (TW)

(73) Assignee: TINNOTEK INC., HSINCHU CITY (TW)

(21) Appl. No.: 13/014,381

(22) Filed: Jan. 26, 2011

(30) Foreign Application Priority Data
Nov. 26, 2010 (TW) 099140962

(51) Int. Cl. H03L 7/00

(52) U.S. Cl. 331/34

(57) ABSTRACT

The present invention discloses a phase-locked loop device and a clock calibration method thereof, wherein the phase-locked loop device comprises a first oscillating module, a second oscillating module, a comparison module and a control module. The first oscillating module generates a first clock signal. The second oscillating module generates a second clock signal. After comparing the first clock signal with the second clock signal, the comparison module generates a difference signal. According to the difference signal, the control module, electrically connected with the first oscillating module, the second oscillating module and the comparison module, interactively tunes the first clock signal and the second clock signal to be as close as possible.

### BACKGROUND OF THE INVENTION

1. Field of the Invention

The present invention relates to a phase-locked loop device and a clock calibration method thereof; in particular, the present invention relates to a phase-locked loop device and a clock calibration method thereof capable of reducing the frequency jitter during frequency tracking processes.

2. Description of Related Art

As the System-On-Chip (SOC) technology becomes mature, the circuitry design of mixed signal has now been comprehensively applied. In general, the conventional phase-locked loop (PLL) partially consists of analog blocks, such as a charge pump and a voltage controlled oscillator (VCO). However, frequent signal conversions between analog signals and digital signals among such circuit blocks operating in such type of PLLs are usually required, thus leading to poor performance of PLL. Additionally, the problem of leakage in the manufacturing process of nanometer complementary metal-oxide-semiconductor (CMOS) is also an issue needed to be overcome.

Compared with conventional PLLs, the all-digital phase-locked loop (ADPLL) exhibits more desirable anti-noise ability and higher stability; besides, the application of ADPLL to differing digital systems turns out to be more convenient. Furthermore, the digitally controlled oscillator (DCO) configured within the ADPLL determines, to a comparatively great extent, the maximum frequency, frequency range and resolution in the ADPLL. But, different from the conventional VCO, the clock period in a DCO is discontinuous. In other word, the entire range of clock is composed of several smaller clock sections. As shown in FIG. 1, such clock sections are partially overlapped to encompass the whole clock range. One common approach currently employed for frequency locking is to perform the sequential tracking which converts from a clock section to another clock section one after the other in a bottom-up fashion.

Nonetheless, for the ADPLL, such an approach of sequential tracking may generate a discontinuous jitter effect. With regards to the design of ADPLL, this poses a serious issue and potentially results in adverse results. At present, after completion of locking action by the ADPLL, the clock frequency may fluctuate due to variations in temperature, further leading to transition of clock sections, thus creating the undesirable jitter effect because of changes in frequency. That is, during an initial frequency locking or re-locking by the ADPLL, it is possible to experience unexpected jitter effects of discontinuity as the result of transition in clock sections. Consequently, in connection with demands, to design an ideal phase-locked loop device and a clock calibration method thereof has now become an urgent subject for commercial applications on market.

### SUMMARY OF THE INVENTION

In view of the aforementioned drawbacks found in prior art, the objective of the present invention is to provide a phase-locked loop (PLL) device and a clock calibration method thereof capable of addressing the issue of discontinuous jitter effect caused by transition of clock sections in the course of initial frequency locking or frequency relocking with currently available PLLs.

According to the objective of the present invention, a phase-locked loop (PLL) device is provided, comprising a first oscillating module, a second oscillating module, a comparison module and a control module. The first oscillating module generates a first clock signal. The second oscillating module generates a second clock signal. After comparing the first clock signal with the second clock signal, the comparison module generates a difference signal. The control module is electrically connected with the first oscillating module, the second oscillating module and the comparison module, and, according to the difference signal, interactively calibrates the first clock signal and the second clock signal to be as close as possible.

Herein the first oscillating module and the second oscillating module further comprise a plurality of clock sections, in which the plurality of clock sections include a first clock section, a second clock section, a third clock section and a fourth clock section, wherein the first oscillating module includes the first clock section and the second clock section, and the first clock section and the second clock section partially overlap with each other; the second oscillating module includes the third clock section and the fourth clock section, and the third clock section and the fourth clock section partially overlap with each other.

Herein, according to the difference signal, the control module calibrates the second clock signal based on the clock of the first clock signal, in which the first clock signal is located in the first clock section and the second clock signal located in the third clock section.

Herein the first clock signal is positioned at an endpoint of the first clock section.

Herein, according to the difference signal, the control module calibrates the first clock signal based on the clock of the second clock signal, in which the first clock signal is located in the second clock section and the second clock signal located in the third clock section.

According to the objective of the present invention, a clock calibration method applicable to a phase-locked loop device is provided. The clock calibration method according to the present invention comprises the following steps: generating a first clock signal with a first oscillating module; generating a second clock signal with a second oscillating module; with a comparison module, comparing the difference between the first clock signal and the second clock signal thereby generating a difference signal; and interactively calibrating the first clock signal and the second clock signal according to the difference signal by means of a control module to be as close as possible.

Herein, the method further comprises, according to the difference signal, calibrating the second clock signal based on the clock of the first clock signal by the control module, in which the second clock signal is located in the third clock section and the first clock signal located in the first clock section.

Herein, the method further comprises, according to the difference signal, calibrating the first clock signal based on the clock of the second clock signal by the control module, in which the first clock signal is located in the second clock section and the second clock signal located in the third clock section.

Herein each of the oscillating modules further includes a first phase-locked unit which locks the first clock signal to a range of target clock.

Herein each of the oscillating modules further includes a second phase-locked unit which is electrically connected to the first phase-locked unit so as to accelerate the speed of locking the first clock signal to a target clock.

Herein each of the oscillating modules further includes a third phase-locked unit which is electrically connected to the first phase-locked unit and the second phase-locked unit so as to enhance the resolution in the first clock signal.

Herein such oscillating modules are standard cell based all-digital oscillating modules.

As described hereinbefore, the phase-locked loop device and clock calibration method thereof according to the present invention provides the following advantages:

the phase-locked loop device and clock calibration method thereof according to the present invention enables the elimination of discontinuous frequency jitter by means of the first oscillating module and the second oscillating module through interactively tuning clock signals thereof in the course of frequency tracking, further generating an almost continuous range of frequency tracking. In addition, the digitally controlled oscillator (DCO) composed of three phase-locked units can offer features of wide range, high locking speed and enhanced resolution in frequency tracking.

### BRIEF DESCRIPTION OF THE DRAWINGS

FIG. 1 shows a diagram illustrating the clock signal tracking process in an embodiment of a phase-locked loop device according to the prior art.

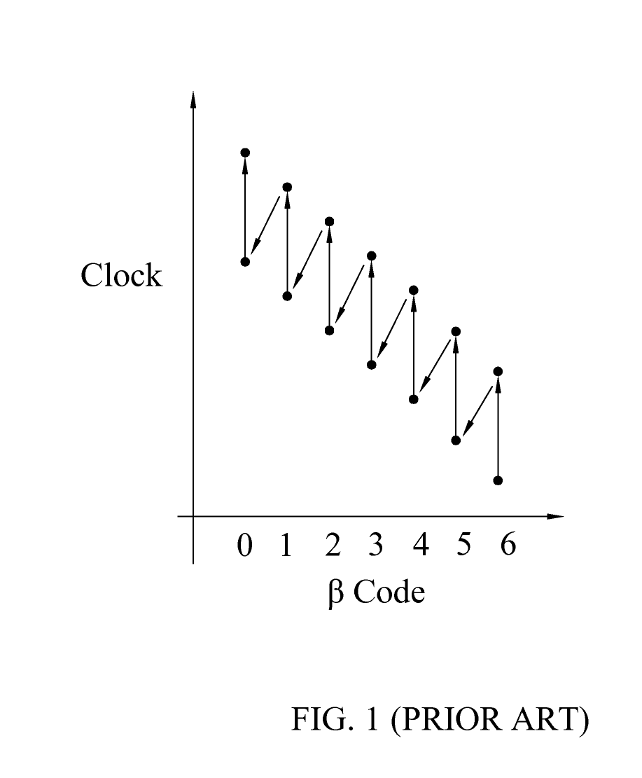

FIG. 2 shows a block diagram for an embodiment of the phase-locked loop device according to the present invention.

FIG. 3 shows a composition diagram for an embodiment of the oscillating module according to the present invention.

FIG. 4 shows a diagram illustrating the clock signal tracking process in an embodiment of the phase-locked loop device according to the present invention.

FIG. 5 shows a diagram illustrating the clock signal calibrating process in an embodiment of the phase-locked loop device according to the present invention.

FIG. 6 shows a flowchart for an embodiment of the clock calibration method according to the present invention.

### DETAILED DESCRIPTION OF THE PREFERRED EMBODIMENTS

In the subsequent texts, references will be made to relevant drawings in order to describe the embodiments for the phase-locked loop device and clock calibration method thereof according to the present invention; to facilitate better appreciations, the same components in the following embodiments will be marked with the identical symbols/numerals throughout the entire specification.

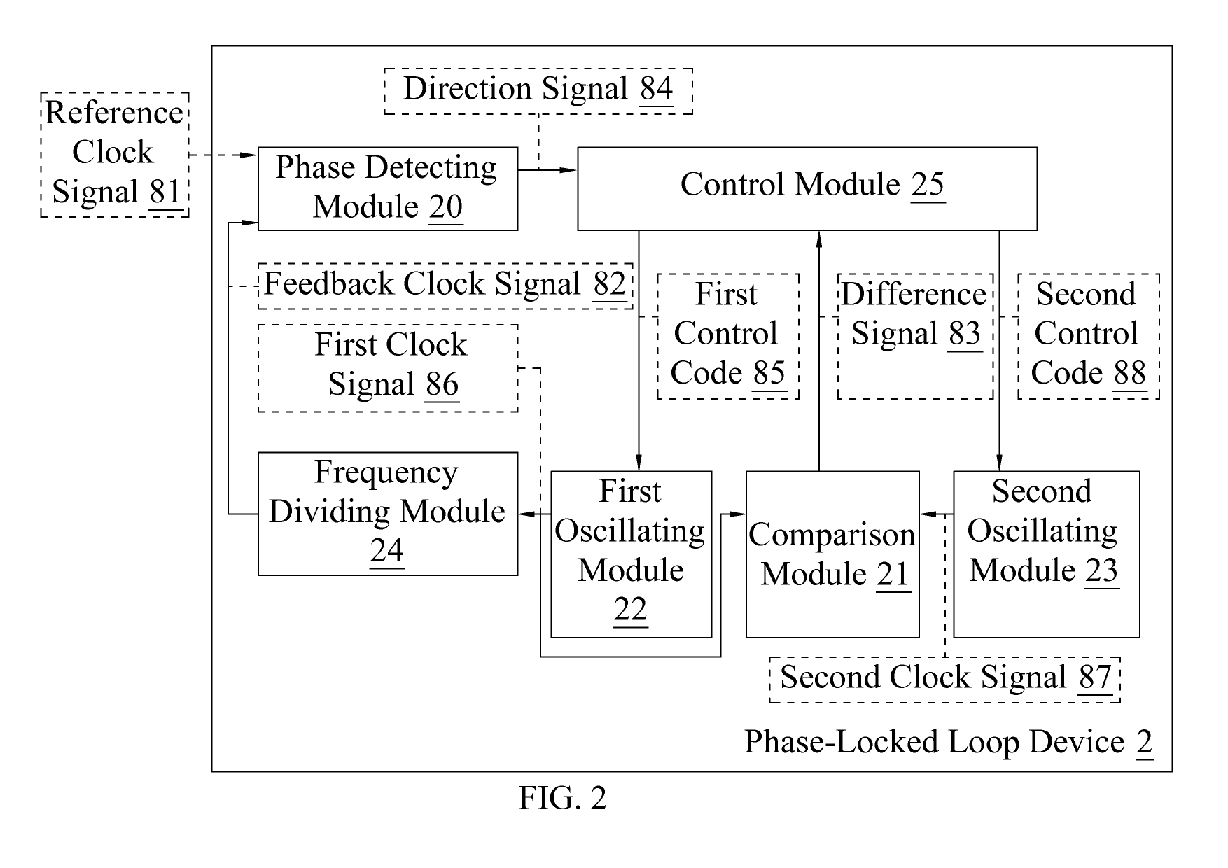

Refer initially to FIG. 2, wherein a block diagram for an embodiment of a phase-locked loop device according to the present invention is shown. As depicted, the phase-locked loop device 2 according to the present invention is a standard cell based all-digital phase-locked loop (ADPLL) comprising a phase detecting module 20, a comparison module 21, a first oscillating module 22, a second oscillating module 23, a frequency dividing module 24 and a control module 25. The phase detecting module 20 is used to detect an externally transferred reference clock signal 81, and a feedback clock signal 82 provided by the frequency dividing module 24. The first oscillating module 22 and the second oscillating module 23 generate the required clock signal, which may be two identical digitally controlled oscillators (DCOs), respectively referred as a DCO and a mirror DCO. The comparison module 21 compares the first oscillating module 22 with the second oscillating module 23 in order to locate the difference in the clock signals thereof, thereby generating a difference signal 83. The control module 25 is electrically connected to the phase detecting module 20, the first oscillating module 22, the second oscillating module 23 and the comparison module 21.

The phase-locked loop device 2 according to the present invention allows two operating modes: (1) phase and frequency tracking mode; and (2) calibrating mode. In the phase and frequency tracking mode, the phase detecting module 20 generates a direction signal 84 to demonstrate the phase polarity in the reference clock signal 81 and the feedback clock signal 82 (preceding or succeeding). In case the reference clock signal 81 precedes the feedback clock signal 82, the direction signal 84 generated by the phase detecting module 20 would be “1”; on the contrary, suppose the reference clock signal 81 succeeds the feedback clock signal 82, the direction signal 84 generated by the phase detecting module 20 would be “0”. As such, the control module 25 can adjust the frequency outputted by the first oscillating module 22 based on the direction signal 84 through updating the first control code 85 (which, in the present embodiment, is the first clock signal 86). Upon completion of frequency locking in the PLL device 2, the feedback clock signal 82 outputted by the frequency dividing module 24 can be consistent with the reference clock signal 81. That is, the frequency and the phase in both signals are consistent.

On the other hand, in the calibrating mode, the control module 25, the comparison module 21, the first oscillating module 22 and the second oscillating module 23 are used to perform interactive adjustments on the calibration mechanism for the first oscillating module 22 and the second oscillating module 23. In such an operating mode, the comparison module 21 receives a first clock signal 86 and a second clock signal 87 respectively outputted by the first oscillating module 22 and the second oscillating module 23, and generates a difference signal 83 according to the difference thereof. Subsequently, in accordance with the difference signal 83 generated by the comparison module 21, the control module 25 interactively calibrates the first clock signal 86 and the second clock signal 87 respectively originated from first oscillating module 22 and the second oscillating module 23 in order to achieve the consistency between these signals.

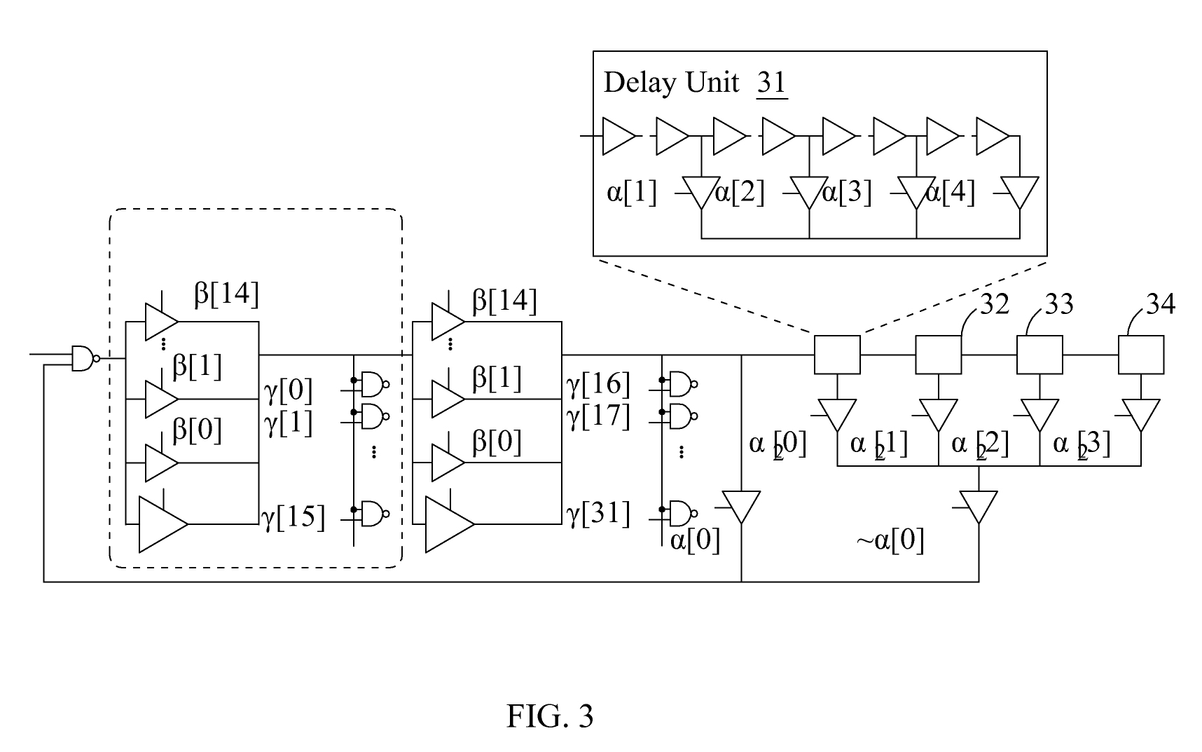

Refer next to FIG. 3, wherein a composition diagram for an embodiment of the oscillating module according to the present invention is shown. As depicted, the first oscillating module 22 and the second oscillating module 23 in the present embodiment can be individually formed by three phase-locked units. Such phase-locked units respectively consists of an α part, a β part and a γ part, each of which parts being electrically connected mutually. In addition, the β part and the γ part form an adjustable delay part.

To further describe each part in details, refer initially to the α part, wherein a serially connected delay chain enabling path selections embodied by the multi-level three-phase buffer can be applied to expand the range of output frequency in the first and the second oscillating modules 22 and 23. Besides, to reduce the impact of delay on the maximum output frequency caused by the serially connected delay chain, the fastest path can be separated as an independent route (i.e., without passing through the delay unit 31, 32, 33 or 34 in any of the delay chains). In other word, only one three-phase buffer can exist in the fastest route. Refer next to the β part, wherein, in each of the adjustable delay part, the three-phase buffer is connected in parallel; herein a β code of 4 digits is used to control the numbers of activated and deactivated three-phase buffers. As the number of activated three-phase buffers increases, additional driving current can be provided such that the entire delay in the delay chain decreases, thereby accelerating the tracking speed.

Refer then to the γ part, wherein the finest resolution in the first and the second oscillating modules 22 and 23 is determined by the γ part. More specifically, the NAND gate array having dual inputs is connected to the output node in each of the adjustable delay parts. By controlling the number of activated NAND gates, it is possible to fine-tune the output frequency of the first and the second oscillating modules 22 and 23. That is, the greater the number of activated NAND gates is, the loading effect occurring at the output node of the connected adjustable delay parts becomes more significant.

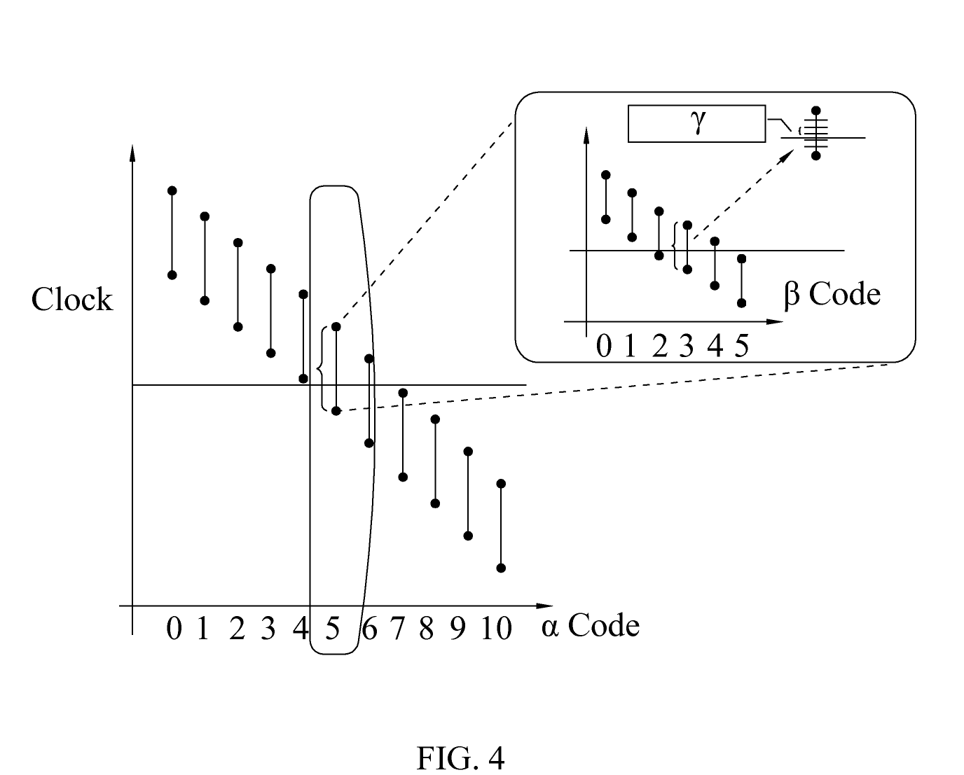

Refer now to FIG. 4, wherein a diagram illustrating the clock signal tracking process in an embodiment of a phase-locked loop device according to the present invention is shown. As depicted, the DCO and the mirror DCO composed of the aforementioned phase-locked units, i.e. the α part, β part and γ part, enable features of wide range, high speed and enhanced resolution for frequency tracking during the sequential tracking process on the reference clock signal 81. The implementations thereof have been illustrated with regards to α part, β part and γ part respectively described in previous texts, which thus are herein omitted for brevity.

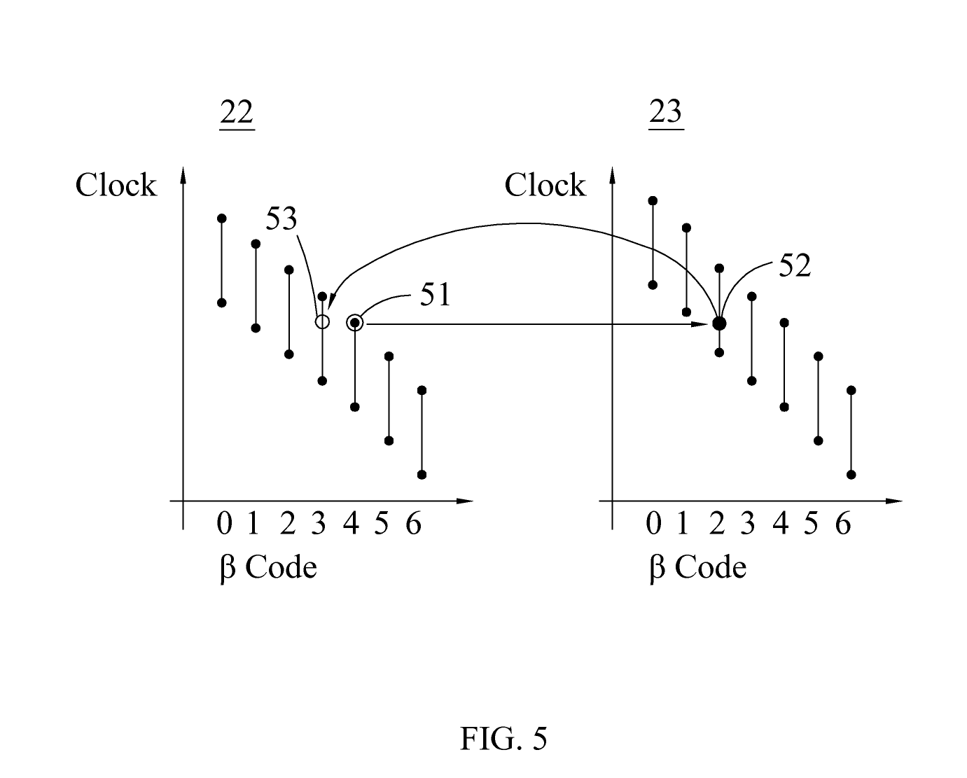

Refer subsequently to FIG. 5, wherein a diagram illustrating the clock signal calibrating process in an embodiment of the phase-locked loop device according to the present invention is shown. As depicted, the present embodiment takes the β code in the first oscillating module 22 and the second oscillating module 23 as an example for describing the calibration process. In tracking the reference clock signal 81, it is assumed that the first clock signal 86 from the first oscillating module 22 is tracked to an upper endpoint 51 of a clock section 4 in the β code (α=0, β=4, γ=0). In this case, the comparison module 21 generates a difference signal 83 according to the difference between the first clock signal 86 and the second clock signal 87. The control module 25 generates a second control code 88 based on the difference signal 83 thereby adjusting the second clock signal 87 outputted by the second oscillating module 23 such that the clock in the second clock signal 87 approaches to the clock in the first clock signal 86. Furthermore, the comparison module 21 continuously generates the difference signal 83 in accordance with the difference between the first clock signal 86 and the second clock signal 87; meanwhile, the control module 25 iteratively adjusts the second clock signal 87 until a first calibration point 52 for the second clock signal 87 in the β code 2 is located (α′=0, β′=2, γ′=8). That is, F_{DCO}(α, γ, γ)=F_{Mirror}(α′, β′, γ′), in which F_{DCO}(•)=F_{Mirror}(•) indicates a conversion equation for the first and the second oscillating module 22, 23, respectively. Upon completion of the calibration process, the clock in the second clock signal 87 of the second oscillating module 23 will be very close to the clock in the first clock signal 86 of the first oscillating module 22.

Similarly, the control module 25 locates a second calibration point 53 corresponding to the second clock signal 87 on another β code 2 contiguous to the original β code 3 in the first oscillating module 22. In other word, the comparison module 21 generates a difference signal 83. Then the control module 25 generates a first control code 85 based on the difference signal 83 so as to adjust the first clock signal 86 on the β code 2 such that the clock in the first clock signal 86 approaches to the clock in the second clock signal 87. Again, the comparison module 21 continuously generates the difference signal 83 in accordance with the difference between the first clock signal 86 and the second clock signal 87; at the same time, the control module 25 iteratively adjusts the first clock signal 86 until the second calibration point 53 for the first clock signal 86 in the β code 3 is located (a=0, β=3, γ=3). In summary of the descriptions in the previous paragraphs, it can be concluded that F_{DCO}(α, β, γ)=F_{Mirror DCO}(α′, β′, γ′)=F_{DCO}(α′, β−1, γ″).

The aforementioned embodiment exemplarily uses the β code of the first oscillating module 22 and the second oscillating module 23 for illustrations, but those skilled ones in the art can conveniently apply other codes (e.g., α code or γ code), which is herein omitted for brevity. In addition, the above-described processes can be repeated until the mapping table for α−β code is well established. Afterward, it can be employed in the process of initial frequency locking or frequency relocking so as to function as a smooth code-jumping mechanism.

Although the concept about the clock calibration method for the phase-locked loop device according to the present invention has been explained along with the descriptions on the phase-locked loop device according to the present invention, to facilitate more thorough understanding, a flowchart thereof is additionally depicted hereunder for detailed explanations.

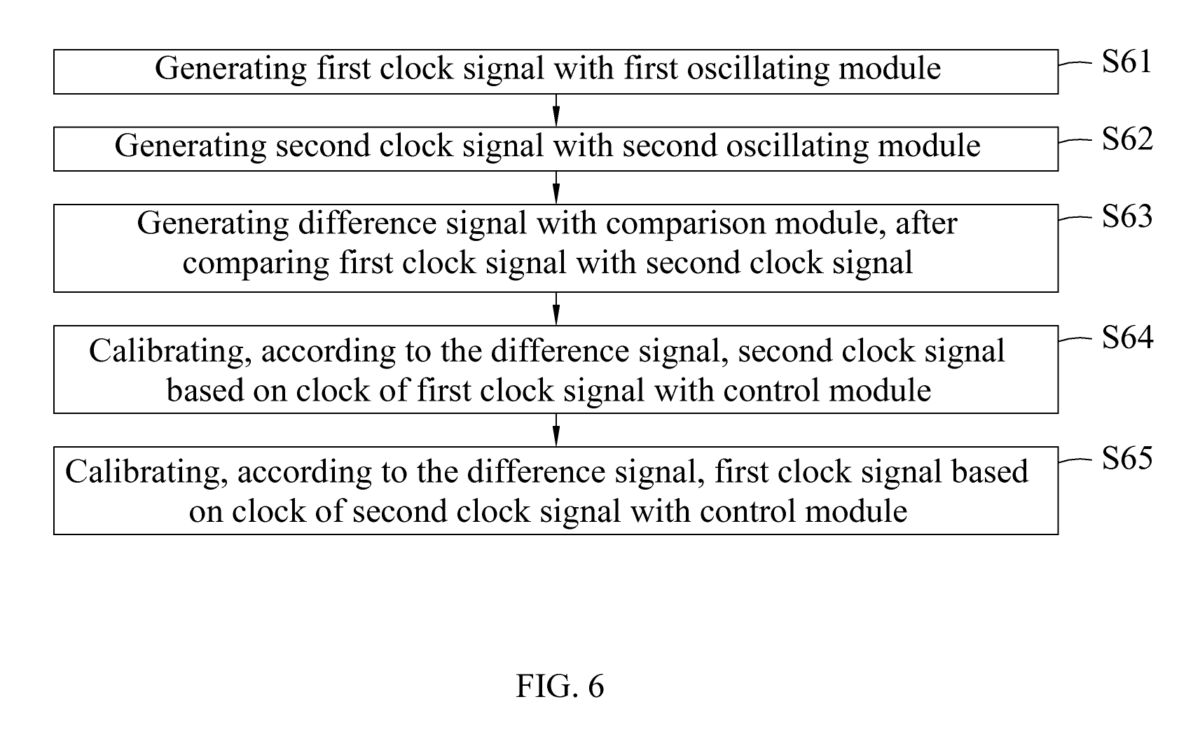

Refer now to FIG. 6, wherein a flowchart for an embodiment of the clock calibration method according to the present invention is shown. As depicted, the clock calibration method according to the present invention is applicable to a phase-locked loop (PLL) device comprising a phase detecting module, a comparison module, a first oscillating module, a second oscillating module, a frequency dividing module and a control module. The clock calibration method for PLL devices according to the present invention comprises the following steps:

(S61) generating a first clock signal with a first oscillating module;

(S62) generating a second clock signal with a second oscillating module;

(S63) after comparing the difference between the first clock signal and the second clock signal, generating a difference signal with a comparison module;

(S64) calibrating the second clock signal toward the clock in the first clock signal according to the difference signal with a control module, in which the second clock signal is located in the third clock section and the first clock signal located in the first clock section; and

(S65) calibrating the first clock signal toward the clock in the second clock signal according to the difference signal with the control module, in which the first clock signal located in the second clock section.

The detailed descriptions about the clock calibration method for PLL devices according to the present invention, along with implementations thereof, have been previously set forth in explaining the PLL device according to the present invention, which is herein omitted for brevity.

In summary, the phase-locked loop device and clock calibration method thereof disclosed in the present invention enables the elimination of discontinuous frequency jitter by means of the first oscillating module and the second oscillating module through interactively tuning clock signals thereof in the course of frequency tracking, further generating an almost continuous range of frequency tracking. Furthermore, the digitally controlled oscillator (DCO) and the mirror DCO composed of three phase-locked units (α, β, γ) can offer features of wide range, high locking speed and enhanced resolution in frequency tracking.

The aforementioned descriptions are exemplary rather than being restrictive. All effectively equivalent changes, alternation or substitutions made thereto without departing from the spirit and scope of the present invention are deemed to be encompassed by the present invention as delineated in the following claims.

What is claimed is:

1. A phase-locked loop (PLL) device, comprising:
a first oscillating module, generating a first clock signal;
a second oscillating module, generating a second clock signal;
a comparison module, after comparing the first clock signal with the second clock signal, generating a difference signal; and
a control module, electrically connected with the first oscillating module, the second oscillating module and the comparison module, and interactively tuning the first clock signal and the second clock signal to be as close as possible.

2. The phase-locked loop (PLL) device according to claim 1, wherein the first oscillating module and the second oscillating module further comprise a plurality of clock sections, in which the plurality of clock sections include a first clock section, a second clock section, a third clock section and a fourth clock section, wherein the first oscillating module includes the first clock section and the second clock section, and the first clock section and the second clock section partially overlap with each other; the second oscillating module includes the third clock section and the fourth clock section, and the third clock section and the fourth clock section partially overlap with each other.

3. The phase-locked loop (PLL) device according to claim 2, wherein, according to the difference signal, the control module calibrates the second clock signal based on the clock of the first clock signal, in which the first clock signal is located in the first clock section and the second clock signal located in the third clock section.

4. The phase-locked loop (PLL) device according to claim 3, wherein the first clock signal is located at an endpoint of the first clock section.

5. The phase-locked loop (PLL) device according to claim 4, wherein, according to the difference signal, the control module calibrates the first clock signal based on the clock of the second clock signal, in which the first clock signal is located in the second clock section and the second clock signal located in the third clock section.

6. The phase-locked loop (PLL) device according to claim 1, wherein each of the oscillating modules further includes a first phase-locked unit capable of locking the first clock signal to a range of target clock and expanding the range of output frequency from the first oscillating module and the second oscillating module.

7. The phase-locked loop (PLL) device according to claim 6, wherein each of the oscillating modules further includes a second phase-locked unit electrically connected with the first phase-locked unit thereby accelerating the speed for locking the first clock signal to a target clock.

8. The phase-locked loop (PLL) device according to claim 7, wherein each of the oscillating modules further includes a third phase-locked unit electrically connected with the first phase-locked unit and the second phase-locked unit, in which the third phase-locked unit tunes the output frequency from the first oscillating module and the second oscillating module thereby increasing the resolution in the first clock signal.

9. The phase-locked loop (PLL) device according to claim 1, wherein such oscillating modules are standard cell based all-digital oscillating modules.

10. A clock calibration method applicable to a phase-locked loop device, comprising the following steps:
generating a first clock signal with a first oscillating module;
generating a second clock signal with a second oscillating module;
after comparing the first clock signal with the second clock signal, generating a difference signal with a comparison module; and
according to the difference signal, interactively tuning the first clock signal and the second clock signal to be as close as possible with a control module.

11. The clock calibration method according to claim 10, wherein the first oscillating module and the second oscillating module further comprise a plurality of clock sections, in which the plurality of clock sections include a first clock section, a second clock section, a third clock section and a fourth clock section, wherein the first oscillating module includes the first clock section and the second clock section, and the first clock section and the second clock section partially overlap with each other; the second oscillating module includes the third clock section and the fourth clock section, and the third clock section and the fourth clock section partially overlap with each other.

12. The clock calibration method according to claim 11, further comprising the following step:
calibrating, according to the difference signal, the second clock signal based on the clock of the first clock signal with a control module, in which the second clock signal is located in the third clock section and the first clock signal located in the first clock section.

13. The clock calibration method according to claim 12, wherein the first clock signal is located at an endpoint of the first clock section.

14. The clock calibration method according to claim 13, further comprising the following step:
calibrating, according to the difference signal, the first clock signal based on the clock of the second clock signal with the control module, in which the first clock signal is located in the second clock section and the second clock signal located in the third clock section.

15. The clock calibration method according to claim 10, further comprising the following step:
locking the first clock signal to a range of target clock with a first phase-locked unit in each of the oscillating modules.

16. The clock calibration method according to claim 15, further comprising the following step:
accelerating the speed for locking the first clock signal to a target clock through a second phase-locked unit in each of the oscillating modules.

17. The clock calibration method according to claim 16, further comprising the following step:
increasing the resolution of the first clock signal with a third phase-locked unit in each of the oscillating modules.

18. The clock calibration method according to claim 10, wherein such oscillating modules are standard cell based all-digital oscillating modules.
